(19) United States
(12) Patent Application Publication
(10) Pub. No.: US 2025/0105030 A1
(43) Pub. Date: Mar. 27, 2025

(54) SUBSTRATE CLEANING DEVICE, AND SUBSTRATE CLEANING METHOD USING THE SAME

(71) Applicant: SAMSUNG ELECTRONICS CO., LTD, Suwon-si (KR)

(72) Inventors: Jieun SEO, Suwon-si (KR); Donghoon KWON, Suwon-si (KR)

(73) Assignee: SAMSUNG ELECTRONICS CO., LTD, Suwon-si (KR)

(21) Appl. No.: 18/782,816

(22) Filed: Jul. 24, 2024

(30) Foreign Application Priority Data
Sep. 21, 2023 (KR) 10-2023-0126577

(51) Int. Cl. H01L 21/67; H01L 21/02

(52) U.S. Cl. CPC H01L 21/67051; H01L 21/02052; H01L 21/67259

(57) ABSTRACT

A substrate cleaning device includes a cleaning module configured to spray a cleaning solution on an upper side of a substrate, a curtain module coupled with the cleaning module and configured to spray a curtain body to at least one of a first area including an upper side of an edge of the substrate, a second area between a cleaner guard at least partially surrounding the substrate and a first upper portion of the edge of the substrate, and a third area including a second upper portion of an outside of the edge of the substrate in parallel to an internal wall of the cleaner guard, and a driver coupled with the cleaning module and configured to horizontally move the cleaning module on a third upper portion of the substrate.

### CROSS-REFERENCE TO RELATED APPLICATIONS

This application claims benefit of priority under 35 U.S.C. § 119 to Korean Patent Application No. 10-2023-0126577, filed on Sep. 21, 2023, in the Korean Intellectual Property Office, the disclosure of which is incorporated by reference herein in its entirety.

### BACKGROUND

### 1. Field

The present disclosure relates generally to semiconductor processes, and more particularly to, a substrate cleaning device and a substrate cleaning method using the same.

### 2. Description of Related Art

Among semiconductor processes, a cleaning process may remove impurities on a surface of a substrate through techniques that may include, but not be limited to, chemical material treatments, gas, physical methods, and the like. In the case of semiconductor processes that deal with fine processes, trace impurities (e.g., particles, metals, organic materials, natural oxide layers, and the like) on the surface of the substrate may have a negative impact on the yield and reliability of semiconductor products, such as, but not limited to, pattern defects and electric characteristic deterioration. Therefore, cleaning processes that clean the substrate may be a significant factor in an overall success of semiconductor processes.

Cleaning processes may be categorized into dipping methods and spraying methods. An example of a dipping method may include submerging the substrate in chemical materials and/or deionized water (DIW). An example of a spray method may include removing impurities by spraying chemical materials in the form of liquid or gas to a rotating substrate.

Recently, a majority of substrates may have been processed using a dipping method (e.g., a batch type), as such a method may provide for substantially simultaneous processing of several substrates at a time. However, spraying methods, which may be better suited for processing a single substrate at a time, may be gaining in popularity along with advancements of fine processes and changes in materials used to manufacture and/or process semiconductors.

In a related spraying method, a high-pressure spray device may be used to spray DIW at a high pressure. For example, the high-pressure spray device may be used to supply the DIW with a relatively high electrical resistance at a relatively high pressure (e.g., over 100 bar). However, foreign particles may reversely flow to the object (e.g., substrate) to be cleaned because of static electricity caused by a friction with the plate wall inside the pipe and/or a friction generated when the DIW is sprayed from a fine nozzle. In order to potentially reduce the possible contamination with foreign particles, the resistivity value of the DIW may be lowered by dissolving a carbon dioxide in the DIW.

### SUMMARY

One or more example embodiments of the present disclosure provide a substrate cleaning device for spraying a curtain body on an upper surface or an outside of an edge of a substrate parallel to a cleaner guard internal wall surrounding the substrate to thereby prevent droplets of a cleaning solution sprayed during a cleaning process or particles removed during the cleaning process from hitting the substrate, being bounced off from the substrate, and colliding with the cleaner guard, or being reflected again from the cleaner guard and contaminating the substrate, and a substrate cleaning method using the same.

According to an aspect of the present disclosure, a substrate cleaning device includes a cleaning module configured to spray a cleaning solution on an upper side of a substrate, a curtain module coupled with the cleaning module and configured to spray a curtain body to at least one of a first area including an upper side of an edge of the substrate, a second area between a cleaner guard at least partially surrounding the substrate and a first upper portion of the edge of the substrate, and a third area including a second upper portion of an outside of the edge of the substrate in parallel to an internal wall of the cleaner guard, and a driver coupled with the cleaning module and configured to horizontally move the cleaning module on a third upper portion of the substrate.

According to an aspect of the present disclosure, a substrate cleaning device includes a cleaning module configured to spray a cleaning solution toward an upper side of a substrate, a curtain module fixed to an internal wall of a cleaner guard and configured to spray a curtain body to at least one of an edge of the substrate and an outside of the edge in parallel to the internal wall of the cleaner guard, the cleaner guard at least partially surrounding the substrate, a driver coupled with the cleaning module and configured to horizontally move the cleaning module on the substrate, and a controller configured to control the curtain module to spray the curtain body based on the cleaning module spraying the cleaning solution on the edge of the substrate.

According to an aspect of the present disclosure, a substrate cleaning method includes rotating an arranged substrate, controlling a cleaning module to spray a cleaning solution on a surface of the substrate, and controlling a curtain module, disposed on at least one of a first upper portion of an edge of the substrate and a second upper portion of an outside of the edge of the substrate, to spray a curtain body between a cleaner guard at least partially surrounding the substrate and at least one of an upper side of the edge of the substrate and the cleaning module, based on the cleaning module spraying the cleaning solution on the edge of the substrate.

Further, one or more example embodiments of the present disclosure provide for a curtain body to be sprayed on the edge or outside of the edge of the substrate to prevent droplets or particles of the cleaning solution generated near the edge of the substrate during the cleaning process from colliding with the cleaner guard and contaminating the substrate again, thereby increasing detergency of the substrate.

Additional aspects may be set forth in part in the description which follows and, in part, may be apparent from the description, and/or may be learned by practice of the presented embodiments.

### BRIEF DESCRIPTION OF DRAWINGS

The above and other aspects, features, and advantages of certain embodiments of the present disclosure may be more apparent from the following description taken in conjunction with the accompanying drawings, in which:

FIG. 1 shows a configuration of a substrate cleaning device, according to an embodiment;

FIGS. 2 to 10 show substrate cleaning devices, according to some embodiments;

FIGS. 11 to 16 show curtain modules of substrate cleaning devices, according to some embodiments; and

FIG. 17 shows a substrate cleaning method using a substrate cleaning device, according to an embodiment.

### DETAILED DESCRIPTION

In the following detailed description, only certain embodiments of the present disclosure have been shown and described, simply by way of illustration. As those skilled in the art may understand, the described embodiments may be modified in various different ways, without departing from the spirit and/or scope of the present disclosure.

The drawings and description are to be regarded as illustrative in nature and not restrictive, and like reference numerals may designate like elements throughout the specification.

The size and thickness of each configuration shown in the drawings may be arbitrarily shown for better understanding and ease of description, however, the present disclosure is not limited thereto. In the drawings, the thickness of layers, films, panels, regions, and the like, may be enlarged for clarity. The thicknesses of some layers and areas may be exaggerated for ease of explanation.

Throughout the present disclosure and the claims that follow, when an element is described as being “coupled” or “connected” to another element, the element may be “directly coupled” to the other element and/or may be “indirectly coupled” to the other element through a third element.

Unless explicitly described to the contrary, the word “comprise”, and variations such as, but not limited to, “comprises” or “comprising”, may be understood to imply the inclusion of stated elements but not the exclusion of any other elements.

It is to be understood that when an element such as a layer, film, region, or substrate is referred to as being “over,” “above,” “on”, “below,” “under,” or “beneath” another element, the element may be directly over, above, below, under, or beneath the other element and/or intervening elements may also be present. Alternatively or additionally, when an element is referred to as being “directly over,” “directly above,” “directly on”, “directly below,” “directly under,” or “directly beneath” another element, there may be no intervening elements present. The word “on” or “above” may refer to being positioned on or below the object portion, and may not necessarily refer to being positioned on the upper side of the object portion based on a gravitational direction.

The phrase “in a plan view” may refer to viewing an object portion from the top, and the phrase “in a cross-sectional view” may refer to viewing a cross-section of which the object portion is vertically cut from the side.

As used herein, when an element or layer is referred to as “covering” another element or layer, the element or layer may cover at least a portion of the other element or layer, where the portion may include a fraction of the other element or may include an entirety of the other element.

As used herein, each of such phrases as “A or B,” “at least one of A and B,” “at least one of A or B,” “A, B, or C,” “at least one of A, B, and C,” and “at least one of A, B, or C,” may include any possible combinations of the items enumerated together in a corresponding one of the phrases. As used herein, such terms as “1st” and “2nd,” or “first” and “second” may be used to simply distinguish a corresponding component from another, and does not limit the components in other aspect (e.g., importance or order).

In the present disclosure, the articles “a” and “an” are intended to include one or more items, and may be used interchangeably with “one or more.” Where only one item is intended, the term “one” or similar language is used.

Reference throughout the present disclosure to “one embodiment,” “an embodiment,” “an example embodiment,” or similar language may indicate that a particular feature, structure, or characteristic described in connection with the indicated embodiment is included in at least one embodiment of the present solution. Thus, the phrases “in one embodiment”, “in an embodiment,” “in an example embodiment,” and similar language throughout this disclosure may, but do not necessarily, all refer to the same embodiment. The embodiments described herein are example embodiments, and thus, the disclosure is not limited thereto and may be realized in various other forms.

It is to be understood that the specific order or hierarchy of blocks in the processes/flowcharts disclosed are an illustration of exemplary approaches. Based upon design preferences, it is understood that the specific order or hierarchy of blocks in the processes/flowcharts may be rearranged. Further, some blocks may be combined or omitted. The accompanying claims present elements of the various blocks in a sample order, and are not meant to be limited to the specific order or hierarchy presented.

As used herein, each of the terms “CO₂”, “N₂”, and the like may refer to a material made of elements included in each of the terms and is not a chemical formula representing a stoichiometric relationship.

Hereinafter, various embodiments of the present disclosure are described with reference to the accompanying drawings.

Hereinafter, a substrate cleaning device and a substrate cleaning method according to example embodiments of the present disclosure are described with reference to the accompanying drawings.

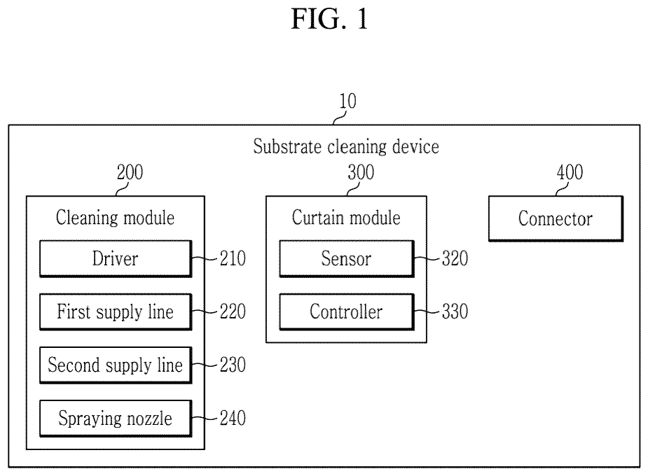

In a semiconductor process, a cluster-tool system may refer to a system in which processes such as, but not limited to, cleaning, oxidation, and thin film deposition may be performed in-situ within the same vacuum system. The cluster-tool system may provide for an increased reliability and/or reproducibility of the semiconductor process. Alternatively or additionally, the cluster-tool system may provide for detergency to be secured by mixing two or more types of solutions and using the mixed solutions as a cleaning solution in a non-contact cleaning process, as described with reference to FIGS. 1 to 17.

The substrate cleaning device and the substrate cleaning method, according to the present disclosure, may be applied to the cluster-tool system and/or to other various types of cleaning processes.

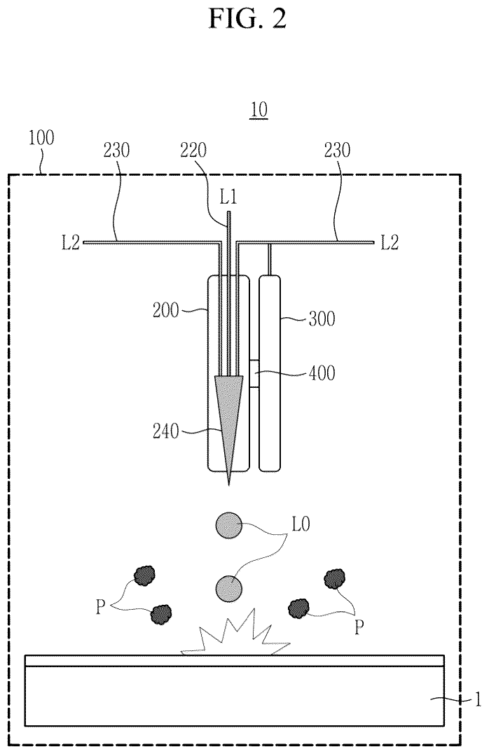

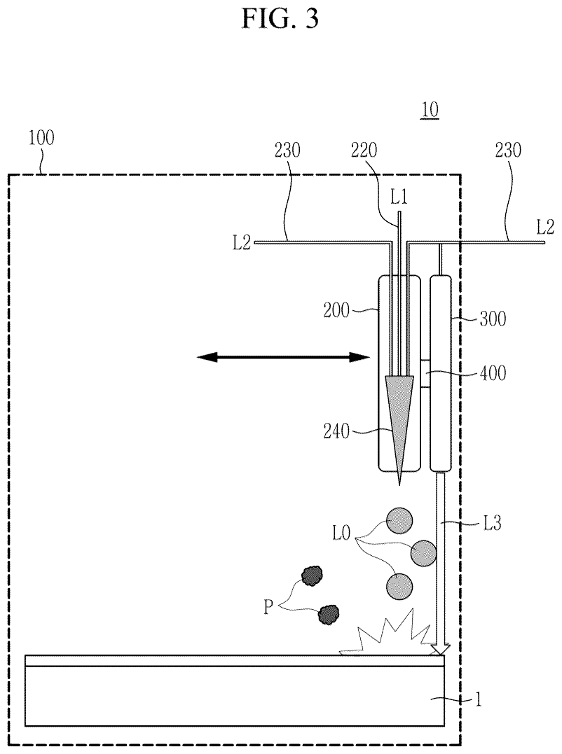

FIG. 1 shows a configuration of a substrate cleaning device, according to an embodiment. FIGS. 2 and 3 show a substrate cleaning device, according to some embodiments.

Referring to FIGS. 1 to 3, the substrate cleaning device 10 may perform a cleaning process in a cleaner guard 100 surrounding the substrate 1. The substrate cleaning device 10 may include a cleaning module 200 configured to spray a cleaning solution L0 at an upper side of the substrate 1, a curtain module 300 connected to the cleaning module 200 and configured to spray a curtain body L3 to the edge of the substrate 1 or between the cleaner guard 100 and the edge of the substrate 1 from the upper side of the edge of the substrate 1 or to an external upper side of the edge of the substrate 1 that may be parallel to an internal wall of the cleaner guard 100. The substrate cleaning device 10 may further include a driver 210 connected to the cleaning module 200 and configured to horizontally move the cleaning module 200 across the substrate 1.

As shown in FIG. 3, the curtain module 300 may be arranged at an upper portion of an edge of the substrate 1 in parallel to an internal wall of the cleaner guard 100. The curtain module 300 may be configured to spray the curtain body L3 to an upper edge surface of the substrate 1 from the upper portion of the edge of the substrate 1, according to an embodiment. The curtain module 300 of the substrate 1 of the substrate cleaning device 10, according to an embodiment, may be arranged on the upper portion of the outside of the edge and may spray the curtain body L3 between the cleaner guard 100 and the edge of the substrate 1 at the upper portion of the outside of the edge of the substrate 1.

The curtain body L3 may be and/or may include, but not be limited to, deionized water (DIW) and/or carbon dioxide (CO₂). For example, the curtain body L3 may be and/or may include a mixed solution of the DIW and carbon dioxide (CO₂). That is, in such an example the curtain body L3 may be and/or may include both a liquid and a gas.

In the process for cleaning the substrate 1, the cleaning module 200 may spray the cleaning solution L0 toward the substrate 1, according to the spraying method.

Although FIGS. 2 and 3 depict various forms of spraying the cleaning solution L0, the present disclosure is not limited in this regard. That is, other forms of spraying the cleaning solution L0 may be performed without deviating from the scope and/or spirit of the present disclosure. For example, as shown in FIGS. 2 and 3, some droplets from the cleaning solution L0 may be sprayed toward the substrate 1 from the cleaning module 200, and/or some particles P may be bound off the substrate 1.

That is, as shown in FIGS. 2 and 3, the droplets of the cleaning solution L0 may be sprayed during the cleaning process and/or the particles P that may have been removed during the cleaning process may hit the substrate 1 and may bound off from the same.

The cleaning module 200 may include a first supply line 220 for supplying a first fluid L1, a second supply line 230 for supplying a second fluid L2, and a spraying nozzle 240 for spraying the cleaning solution L0, which may be and/or may include the mixed fluid of the first fluid L1 and the second fluid L2.

According to an embodiment, the first fluid L1 supplied by the first supply line 220 may be a DIW mixed solution including DIW and/or carbon dioxide (CO₂), and the second fluid L2 supplied by the second supply line 230 may be nitrogen (N₂). According to another embodiment, the first fluid L1 supplied by the first supply line 220 may be and/or may include nitrogen (N₂), and the second fluid L2 supplied by the second supply line 230 may be and/or may include a DIW mixed solution including DIW and/or carbon dioxide (CO₂). That is, the present disclosure is not limited in this regard.

The curtain body L3 may be and/or may include DIW, carbon dioxide (CO₂), and/or may be and/or may include a mixed solution of DIW and carbon dioxide (CO₂). The curtain body L3 may be supplied from the first fluid L1 and/or the second fluid L2 as described below.

Although FIGS. 2 and 3 show the first supply line 220 as one line and the second supply line 230 as two lines, the present disclosure is not limited in this regard. That is, the number, shape, and/or arrangement structure of the first and/or second supply lines may not be limited to the configurations depicted in the drawings.

In some embodiments, the curtain module 300 of the substrate cleaning device 10, as shown in FIG. 3, may not be connected to a supply line for supplying an additional fluid. For example, the curtain module 300 may be connected to a portion of the second supply line 230 for supplying the second fluid L2 from among the cleaning solution L0 and may receive the curtain body L3.

In such embodiments, the second fluid L2 may be and/or may include a DIW mixed solution including DIW and/or carbon dioxide (CO₂) from which the curtain body L3 may be supplied. That is, the curtain body L3 may be and/or may include at least one of DIW, carbon dioxide (CO₂), and a mixture of DIW and carbon dioxide (CO₂).

Although FIG. 3 depicts the curtain body L3 as being supplied from the second supply line 230, the present disclosure is not limited is this regard. For example, the curtain body L3 may be and/or may include DIW, carbon dioxide (CO₂), and/or a mixed fluid including DIW and carbon dioxide (CO₂), and the curtain body L3 may be supplied from the first supply line 220 and/or the second supply line 230 depending on types of the first fluid L1 and/or the second fluid L2.

As shown in FIG. 3, the cleaning module 200 and the curtain module 300 may move to the edge of the substrate 1 from a center of the substrate 1 by the driver 210.

When the curtain module 300 is disposed on the edge of the upper side of the substrate 1 and the cleaning module 200 sprays the cleaning solution L0 at the edge of the substrate 1 as the cleaning module 200 moves horizontally, the curtain module 300 may, as shown in FIG. 3, spray the curtain body L3 at the upper side of the edge of the substrate 1 in parallel to the internal wall of the cleaner guard 100 surrounding the substrate 1.

The curtain body L3 may be sprayed on the upper side of the edge of the substrate 1. In some embodiments, the curtain body L3 may be sprayed on the upper side of the outside of the edge of the substrate 1, that is, between the edge of the substrate 1 and the cleaner guard 100.

That is, the curtain module 300 may be placed on the upper side of the edge of the substrate 1 and the curtain body L3 may be sprayed on the upper side of the edge of the substrate 1, and the curtain module 300 may be disposed nearer the outside on the upper side of the edge of the substrate 1 and/or may be disposed on the outside.

In an embodiment, the curtain module 300 may be disposed between a circumference of the substrate 1 and the cleaner guard 100 so that the curtain body L3 may be sprayed toward a lower side of the outside of circumference of the substrate 1 and not toward the upper side of the substrate 1.

The driver 210 may be connected to the cleaning module 200 and may serve to horizontally move the cleaning module 200 at the upper portion of the substrate 1.

The driver 210, which is a component of the cleaning module 200, is not limited thereto and may move the cleaning module 200 as long as the driver 210 has a structure that may move the cleaning module 200.

The driver 210 may be connected to any part of the cleaning module 200 and may be disposed in a position where the driver 210 may move the cleaning module 200 horizontally.

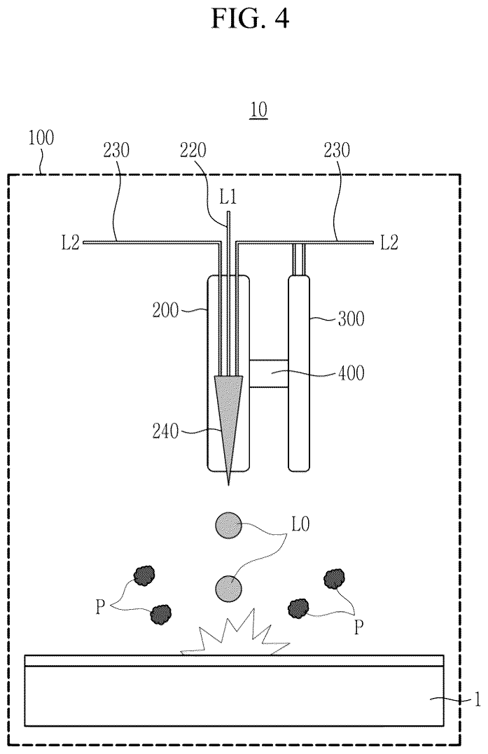

For example, the cleaning module 200 including the supply lines 220 and 230 and the spraying nozzle 240 may further include a housing in which a structure in which the supply lines 220 and 230 and the spraying nozzle 240 are connected, as described with reference to FIGS. 4 to 10.

The driver 210 may be connected to the housing and may simultaneously move the housing and all components connected within the housing. For example, the respective supply lines 220 and 230 may have a structure in which one side remains connected to a portion of the housing of the cleaning module 200, and may move horizontally together.

When the curtain module 300 is disposed at the edge of the upper side of the substrate 1 as the cleaning module 200 moves horizontally, and the cleaning module 200 sprays the cleaning solution L0 at the edge of the substrate 1, the curtain module 300 may include a controller 330 for controlling the curtain body L3 to be sprayed.

The curtain module 300 of the substrate cleaning device 10 may spray the curtain body L3 including a predetermined component of the cleaning solution L0 on the edge of the substrate 1 or the outside of the upper side of the edge of the substrate 1. That is, the curtain module 300 may spray the curtain body L3 between the circumference of the substrate 1 and the cleaner guard 100 in parallel to the internal wall of the cleaner guard 100 surrounding the substrate 1.

In an embodiment, the curtain module 300 may be placed on the upper portion of the edge of the substrate 1 or may be placed in the space between the circumference of the substrate 1 and the cleaner guard 100 at the time of spraying the curtain body L3, and hence, the curtain module 300 may spray the curtain body L3 toward a space between the edge of the substrate 1 or the external side of the circumference of the substrate 1 and the cleaner guard 100.

Consequently, the droplets and/or the particles P removed during the cleaning process, caused by the cleaning solution L0 sprayed for the cleaning process, may be prevented from hitting the substrate 1, and/or bouncing off from the same, colliding with cleaner guard 100. When the droplets and/or the particles P already bounced off to the cleaner guard 100, the contaminated materials bouncing off again from the cleaner guard 100 and falling toward the substrate 1 may be blocked, and the substrate 1 may be prevented from being contaminated during the cleaning process.

In some embodiments, the substrate cleaning device 10 may include a sensor 320 for detecting the cleaning module 200 disposed at the edge of the substrate 1.

In an embodiment, the sensor 320 may be included in the curtain module 300, and may sense whether the cleaning module 200 is disposed near the curtain module 300 or whether the cleaning module 200 is disposed near the edge of the substrate 1.

Alternatively or additionally, the sensor 320 may be included in the cleaning module 200 and not the curtain module 300, and in such an embodiment, the sensor 320 may sense whether the cleaning module 200 is disposed near the edge of the substrate 1 or may sense whether the cleaning module 200 moves near the curtain module 300 disposed near the edge of the substrate 1.

According to the present disclosure, the substrate cleaning device 10 may include a connector 400 for connecting (e.g., coupling) the cleaning module 200 and the curtain module 300.

The connector 400 may connect the cleaning module 200 and the curtain module 300, and by connecting any part of the cleaning module 200 and the curtain module 300, the position and method for connecting the connector 400 may not be limited when the cleaning module 200 and the curtain module 300 may move simultaneously.

FIGS. 4 to 6 show a substrate cleaning device, according to an embodiment.

Referring to FIGS. 4 to 6, the connector 400 may have its length adjusted along the horizontal direction in which the cleaning module 200 moves. In an embodiment, the connector 400 may be and/or may include a pneumatic tube and may be operated to extend in the horizontal direction. Alternatively or additionally, the connector 400 may have a bellows structure.

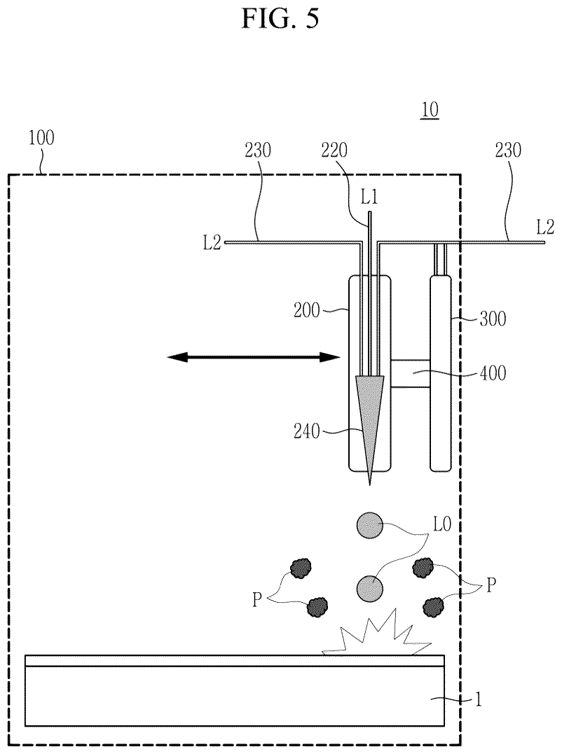

As shown in FIG. 4, the cleaning module 200 may clean with cleaning solution L0 near the center of the substrate 1. As shown in FIG. 5, the cleaning module 200 and the curtain module 300 may move horizontally together near the cleaner guard 100, for example, near the edge of the substrate 1.

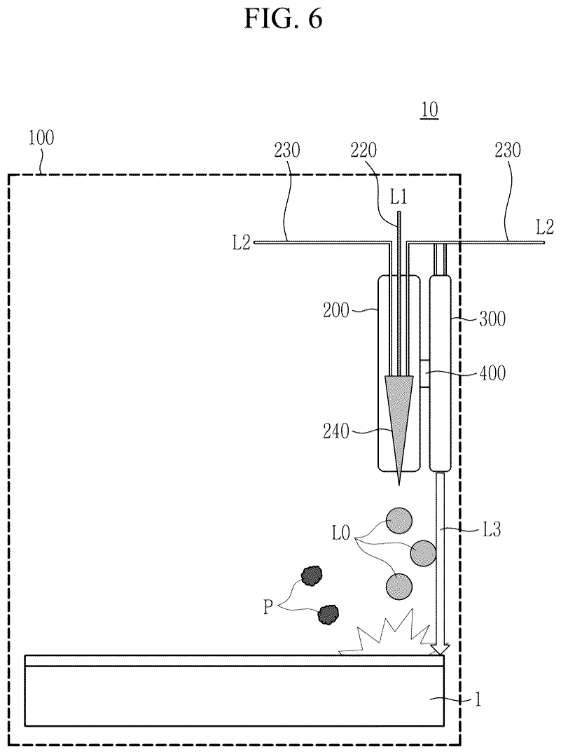

As shown in FIG. 6, the cleaning module 200 may move near the edge of the substrate 1, compared to FIG. 5, and may spray the cleaning solution L0, and the curtain module 300 may spray the curtain body L3 to the upper side of the edge of the substrate 1. As such, a length of the connector 400 may be further reduced when compared to FIG. 5.

When the cleaning solution L0 is sprayed at the circumference of the substrate 1, the droplets of the cleaning solution L0 and the particles P removed from the substrate 1 may collide with the cleaner guard 100 disposed near so when the curtain body L3 is sprayed at the curtain module 300 disposed between the upper portion of the edge of the substrate 1, the edge circumference and the cleaner guard 100, the droplets of the cleaning solution L0 and the particles P may be swept downward together along the curtain body L3 by the curtain body L3.

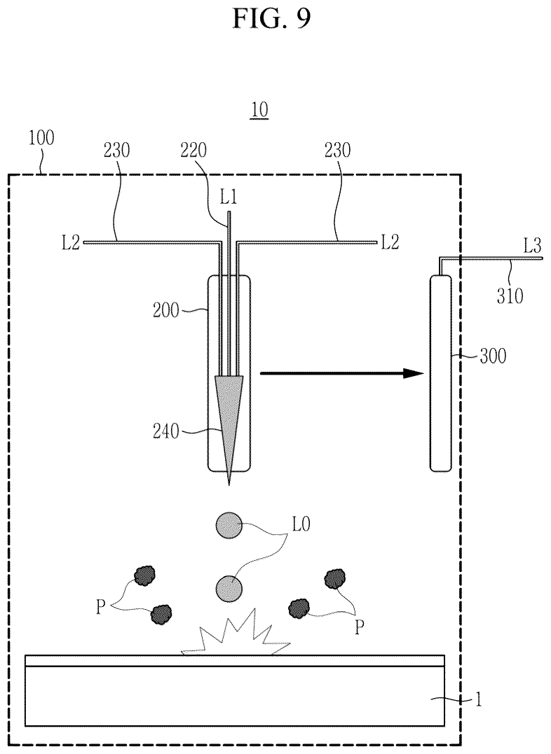

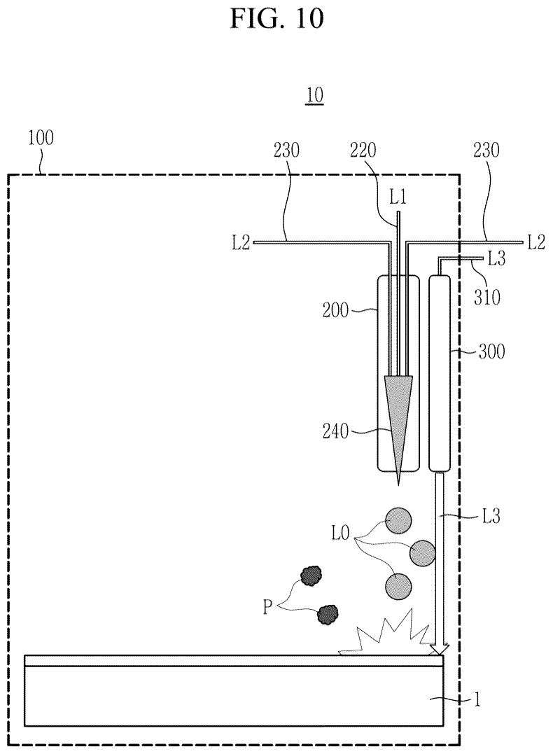

Referring to FIGS. 9 and 10, the curtain module 300 may be fixed to the internal wall of the cleaner guard 100, the curtain module 300 and the cleaning module 200 may be connected through the length-adjustable connector 400, and the cleaning module 200 may clean the substrate 1 by moving on the upper side of the substrate 1.

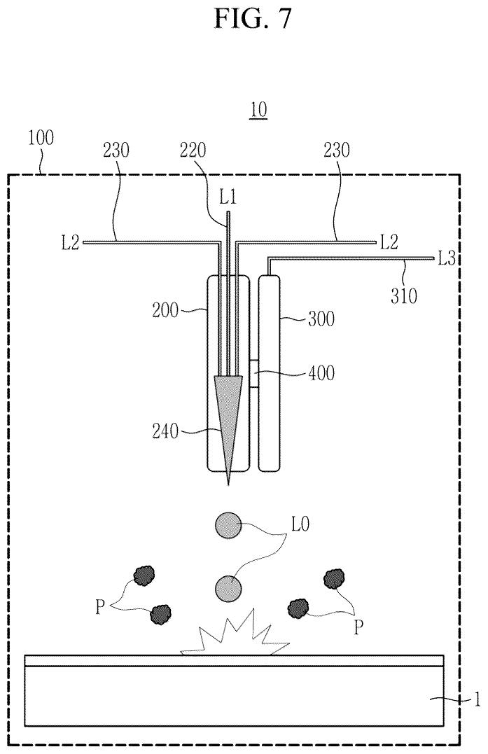

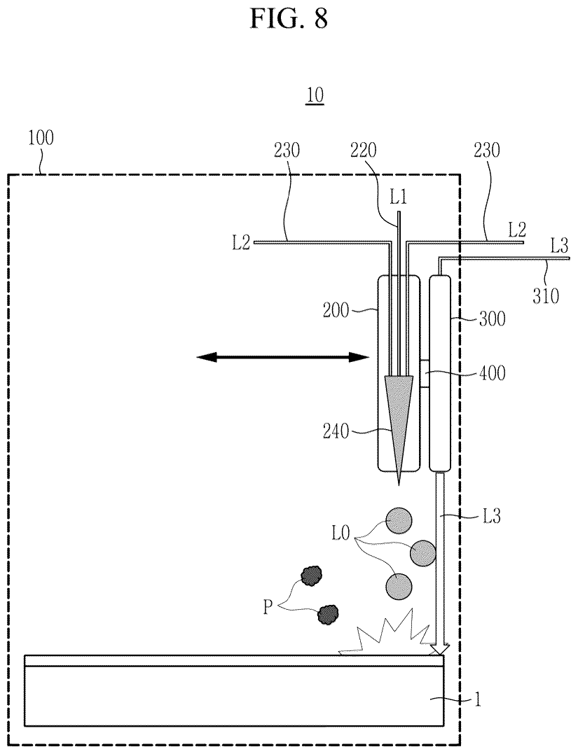

Referring to FIGS. 7 and 8 show a substrate cleaning device, according to an embodiment.

As shown in FIGS. 7 and 8, the curtain module 300 of the substrate cleaning device 10 may have a structure in which a supply line is connected to supply a separate fluid.

For example, the curtain module 300 may include a separate third supply line 310 for supplying the curtain body L3. For example, the curtain body L3 supplied through the third supply line 310 may be and/or may include DIW, carbon dioxide (CO₂), and/or a mixed solution of DIW and carbon dioxide (CO₂).

The embodiments shown in FIGS. 7 and 8 may differ in that the curtain module 300 may be individually driven, and the control relating to the supply of the curtain body L3 may be independently performed from the control of the cleaning solution L0 of the cleaning module 200 when the curtain module 300 is connected to the separate third supply line 310 and receives a supply while the curtain module 300 (e.g., see FIGS. 2 and 3) is connected to a portion of the second supply line 230 and receives the curtain body L3 therefrom.

In an embodiment, the curtain module 300 including the separate third supply line 310 may further include a curtain module driver for enabling an independent movement of the curtain module 300, separate from the driver 210 for moving the cleaning module 200.

FIGS. 9 and 10 show a substrate cleaning device, according to an embodiment.

As shown in FIG. 9, the substrate cleaning device 10 may perform a cleaning process inside the cleaner guard 100 surrounding the substrate 1. The substrate cleaning device 10 may include a cleaning module 200 for spraying the cleaning solution L0 on the upper side of the substrate 1, and a curtain module 300 fixed to the internal wall of the cleaner guard 100 for spraying the curtain body L3 toward the upper side of the edge of the substrate 1 or the outside of the edge of the substrate 1 in parallel to the internal wall of the cleaner guard 100.

Although in FIG. 9 the curtain module 300 is depicted as being disposed on the upper portion of the edge of the substrate 1, the present disclosure is not limited in this regard. For example, the curtain module 300 may be disposed in the upper portion of the outside of the edge of substrate 1, for example, between the cleaner guard 100 and the circumference of the substrate 1.

The cleaning module 200 may include a first supply line 220 for supplying the first fluid L1, a second supply line 230 for supplying the second fluid L2, and a spraying nozzle 240 for spraying a mixed fluid of the first fluid L1 and the second fluid L2.

The curtain module 300 may include a third supply line 310 for supplying the curtain body L3, and the curtain body L3 may be and/or may include DIW, carbon dioxide (CO₂), and/or a mixed solution including DIW and carbon dioxide (CO₂).

The curtain module 300 may include a separate third supply line 310 connected to the curtain module 300 for supplying the curtain body L3. In such an embodiment, the curtain body L3 that may be supplied through the third supply line 310 may be and/or may include DIW, carbon dioxide (CO₂), and/or a mixed solution of DIW and carbon dioxide (CO₂).

The substrate cleaning device 10 shown in FIGS. 9 and 10 may selectively include the respective components described in the substrate cleaning device 10 shown in FIGS. 1 to 8, excluding that the cleaning module 200 and the curtain module 300 may not be connected to each other by the connector 400 and may be individual modules.

For example, the substrate cleaning device 10 may include a driver 210 connected to the cleaning module 200 to horizontally move the cleaning module 200 on the upper portion of the substrate 1, and the curtain module 300 may include a controller 330 for controlling the spraying of the curtain body L3 when the cleaning module 200 is disposed near the edge upper side of the substrate 1 and sprays the cleaning solution L0.

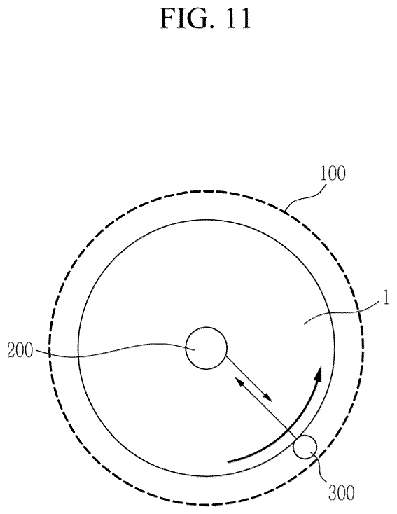

FIGS. 11 to 16 show a curtain module of a substrate cleaning device, according to an embodiment.

Referring to FIGS. 11 to 16, top views of the substrate cleaning device 10 are illustrated. In an embodiment, during the cleaning process, the substrate 1 may rotate, and the cleaning module 200 may move between the center and the circumference of the substrate 1 and may carry out the cleaning job by spraying the cleaning solution L0.

Referring to FIGS. 11 16, an embodiment in which the curtain module 300 may be disposed between the outside of the circumference of the substrate 1 and the internal wall of the cleaner guard 100 is depicted.

FIGS. 11 to 16 show a structure in which the curtain module 300 may be disposed on the outside of the substrate 1 to contact the edge of the substrate 1, and may be disposed on the inside of the cleaner guard 100 so that the portion where the curtain body L3 is sprayed may not contact the internal wall of the cleaner guard 100.

Although FIGS. 11 to 16 depict the cleaning module 200 and curtain module 300 as separate modules, and the connector 400 is not shown, the present disclosure is not limited in this regard. That is, FIGS. 11 to 16 are shown to describe various embodiments of the curtain module 300, and the respective configurations and structures are not limited to what is shown.

That is, the curtain module 300 may be an independent structure that is separate from the cleaning module 200, and may be fixed to the internal wall of the cleaner guard 100, and as shown in FIGS. 2 to 8, the curtain module 300 may be connected to the cleaning module 200 through the connector 400 and may move together to the edge of the substrate 1 from the center of the substrate 1.

The connector 400 for connecting the curtain module 300 and the cleaning module 200 may have a length-adjustable structure, and regardless of the position of the cleaning module 200, the curtain module 300 may be fixed to the outside of the edge of the substrate 1 by increasing the length of the connector 400.

The cross-section that may be parallel to the substrate 1 of the curtain module 300 may have various shapes as shown in FIGS. 11 to 16, and the curtain body L3 may be sprayed in the shape of the cross-section of the curtain module 300 that is parallel to the substrate 1.

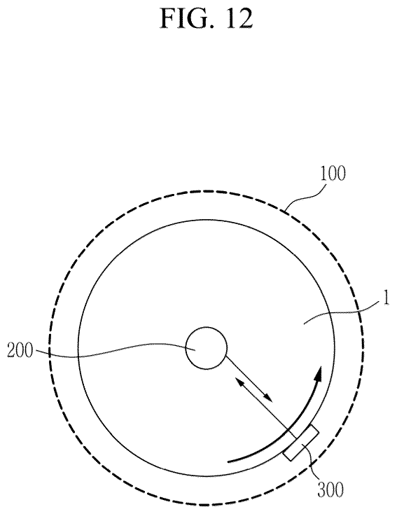

For example, as shown in FIG. 11, the cross-section of the curtain module 300 may be circular. As another example, as shown in FIG. 12, the cross-section of the curtain module 300 may have a bar shape of which a side facing the substrate 1 has a length.

The bar-shaped curtain module 300 shown in FIG. 12 may have a wider structure covering the cleaner guard 100 than the circular curtain module 300 in FIG. 11. Accordingly, when the droplets of the cleaning solution L0 sprayed near the edge of the substrate 1 and the removed particles P are about to collide with the cleaner guard 100, the curtain module 300 in the type shown in FIG. 12 may cover a wider area than the case of FIG. 11 in terms of preventing collision.

Accordingly, the bar-shaped curtain module 300 may be more effective in preventing the droplets and the removed particles P from colliding with the cleaner guard 100, and the bar-shaped curtain module 300 may also be more effective in preventing reverse contamination that may occur when the droplets and the removed particles P return to the substrate 1 after colliding with the cleaner guard 100.

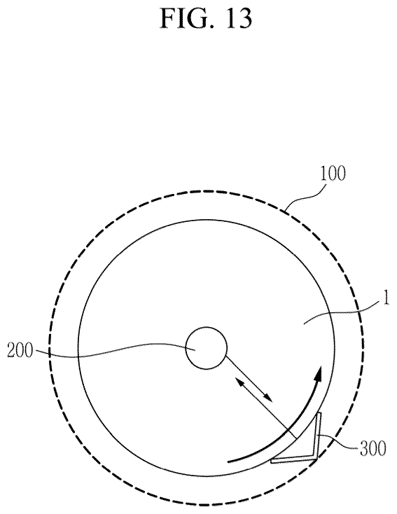

Additionally, as shown in FIG. 13, the cross-section of the curtain module 300 may have a long rod shape that may be bent. The bent angle may not be limited to what is shown, and although a single curved structure is shown in the drawing, the cross-section of the curtain module 300 may have one or more curved structures connected together.

FIGS. 11 13 show a curtain module 300 disposed in the substrate cleaning device 10. According to various embodiments, a plurality of curtain modules 300 may be disposed in the substrate cleaning device 10.

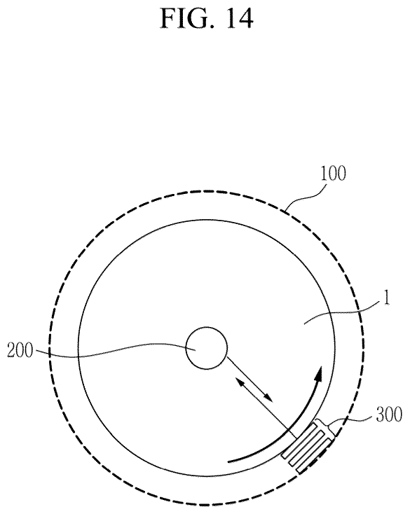

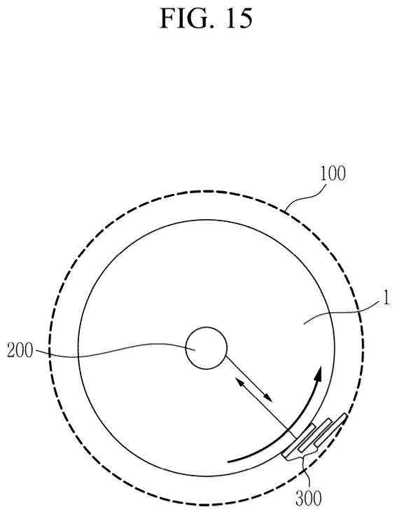

FIG. 14 shows an embodiment in which three (3) curtain modules 300 with cross-sections that have a bar shape, completely overlap each other. FIG. 15 shows an embodiment in which the three (3) curtain modules 300 partially overlap each other.

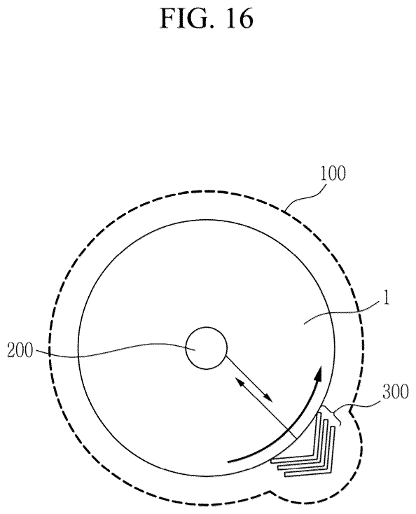

FIG. 16 shows an embodiment in which the shape of the cross-section of the curtain module 300 differs depending on the internal wall structure of the cleaner guard 100, that is, the shape of the cross-section.

The cleaner guard 100 shown in FIG. 16 has a portion on a side that protrudes, and does not have a completely cylindrical shape shown in FIGS. 11 to

In such an embodiment, the shape of the curtain module 300 may be arranged to correspond with the protruding portion of the cleaner guard 100, and as such, may be arranged to protrude as shown in FIG. 16.

When the curtain modules 300 are arranged as shown in FIGS. 14 to 16 described above, at least some of the curtain modules 300 may overlap each other.

The curtain module 300 may spray the curtain body L3 in the form of the cross-section of the curtain module 300 that is parallel to the substrate 1 so the curtain body L3 may be sprayed as if forming a film that is like stretching the curtain to cover the cleaner guard 100.

Accordingly, when some of the curtain modules 300 are arranged to overlap each other, the curtain may have the effect of being stretched in multiple layers in the overlapping part so the reverse contamination of the substrate 1 caused by reaching the cleaner guard 100 or the bouncing off from the cleaner guard 100 may be blocked tightly as a result.

When the curtain modules 300 are arranged in this manner, the supply lines supplying the curtain body L3 may be connected to the supply line supplying the cleaning solution L0 to receive the curtain body L3. However, the present disclosure is not limited thereto, and separate supply lines may be provided as shown in FIGS. 7 and 8.

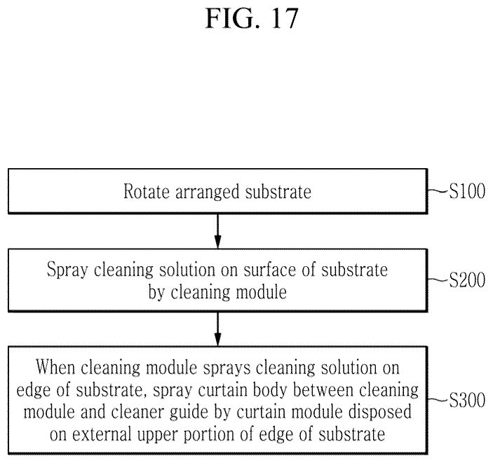

FIG. 17 shows a substrate cleaning method using a substrate cleaning device, according to an embodiment.

As shown in FIG. 17, the substrate cleaning method, according to the present disclosure may include: rotating the arranged substrate 1 (operation S100); allowing the cleaning module 200 to spray the cleaning solution L0 on the surface of the substrate 1 (operation S200); and allowing the curtain module 300 disposed on the upper portion of the edge of the substrate 1 or the upper portion of the outside of the edge to spray the curtain body L3 between the cleaning module 200 and the cleaner guard 100, in detail, between the cleaning solution L0 sprayed by the cleaning module 200 and the cleaner guard 100 (operation S300) in a cleaning process performed in the cleaner guard 100 surrounding the substrate 1.

In an embodiment, the substrate cleaning method may include controlling the sensor 320 to sense the cleaning module 200 to spray the cleaning solution L0 when disposed on the edge of the substrate 1.

The spraying of the cleaning solution L0 in S200 may include mixing the first fluid L1 supplied from the first supply line 220 and the second fluid L2 supplied from the second supply line 230, and spraying the mixed cleaning solution L0 through the spraying nozzle 240 facing the upper side of the substrate 1, and the spraying of the curtain body L3 in S300 may prevent the particles P generated when spraying the cleaning solution L0 from colliding with the internal wall of the cleaner guard 100 as the curtain module 300 sprays the curtain body L3 in parallel to the internal wall of the cleaner guard 100.

As described above, the substrate cleaning device 10, according to the present disclosure, and the substrate cleaning method using the same, may spray the spray curtain body L3 on the outside of the upper side of the edge of the substrate 1 in parallel with the internal wall of the cleaner guard 100 surrounding the substrate 1, thereby preventing the droplets of the cleaning solution L0 sprayed during the cleaning process or the particles P removed during the cleaning process from hitting the substrate 1, bouncing off, and colliding with the cleaner guard 100, or reflecting once more from the cleaner guard 100 to reversely contaminate the substrate 1.

While the present disclosure has been described in connection with what is presently considered to be practical embodiments, it is to be understood that the disclosure is not limited to the disclosed embodiments, but, on the contrary, is intended to cover various modifications and equivalent arrangements included within the spirit and scope of the appended claims.

What is claimed is:

1. A substrate cleaning device comprising:
a cleaning module configured to spray a cleaning solution on an upper side of a substrate;
a curtain module coupled with the cleaning module and configured to spray a curtain body to at least one of a first area comprising an upper side of an edge of the substrate, a second area between a cleaner guard at least partially surrounding the substrate and a first upper portion of the edge of the substrate, and a third area comprising a second upper portion of an outside of the edge of the substrate in parallel to an internal wall of the cleaner guard; and
a driver coupled with the cleaning module and configured to horizontally move the cleaning module on a third upper portion of the substrate.

2. The substrate cleaning device of claim 1, wherein the cleaning module comprises:
a first supply line configured to supply a first fluid;
a second supply line configured to supply a second fluid; and
a spraying nozzle configured to spray a mixed fluid of the first fluid and the second fluid.

3. The substrate cleaning device of claim 2, wherein the first fluid comprises at least one of deionized water (DIW) and a DIW mixed solution comprising carbon dioxide (CO₂),
wherein the second fluid comprises nitrogen (N₂), and
wherein the curtain body comprises at least one of DIW, carbon dioxide (CO₂), and a mixed solution of DIW and carbon dioxide (CO₂).

4. The substrate cleaning device of claim 2, wherein the first fluid comprises nitrogen (N₂),
wherein the second fluid comprises at least one of deionized water (DIW) and a DIW mixed solution comprising carbon dioxide (CO₂), and
wherein the curtain body comprises at least one of DIW, carbon dioxide (CO₂), and a mixed solution of DIW and carbon dioxide (CO₂).

5. The substrate cleaning device of claim 2, wherein the curtain module is further configured to receive the curtain body from at least one of the first supply line and the second supply line.

6. The substrate cleaning device of claim 2, further comprising:
a third supply line coupled with the curtain module and configured to supply the curtain body,
wherein the curtain body is at least one of deionized water (DIW), carbon dioxide (CO₂), and a mixed solution comprising DIW and carbon dioxide (CO₂).

7. The substrate cleaning device of claim 1, further comprising:
a sensor configured to sense the cleaning module on the edge of the substrate.

8. The substrate cleaning device of claim 1, further comprising:
a controller configured to control the curtain module to spray the curtain body based on the curtain module being disposed on the first upper portion of the edge of the substrate, as the cleaning module moves horizontally, and to control the cleaning module to spray the cleaning solution.

9. The substrate cleaning device of claim 1, further comprising:
a connector coupling with the cleaning module and the curtain module,
wherein a length of the connector is adjusted along a horizontal direction in which the cleaning module moves.

10. The substrate cleaning device of claim 9, wherein the connector comprises a pneumatic tube and is configured to extend in the horizontal direction.

11. The substrate cleaning device of claim 9, wherein the connector comprises a bellows structure.

12. The substrate cleaning device of claim 1, wherein the curtain module comprises a plurality of curtain modules, and
wherein the plurality of curtain modules at least partially overlap each other.

13. The substrate cleaning device of claim 1, wherein a first form of a first cross-section of the curtain module parallel to the substrate becomes different based on a second form of a second cross-section of the cleaner guard.

14. The substrate cleaning device of claim 1, wherein the curtain module is further configured to spray the curtain body in a form of a cross-section of the curtain module parallel to the substrate.

15. A substrate cleaning device comprising:
a cleaning module configured to spray a cleaning solution toward an upper side of a substrate;
a curtain module fixed to an internal wall of a cleaner guard and configured to spray a curtain body to at least one of an edge of the substrate and an outside of the edge in parallel to the internal wall of the cleaner guard, the cleaner guard at least partially surrounding the substrate;
a driver coupled with the cleaning module and configured to horizontally move the cleaning module on the substrate; and
a controller configured to control the curtain module to spray the curtain body based on the cleaning module spraying the cleaning solution on the edge of the substrate.

16. The substrate cleaning device of claim 15, wherein the cleaning module comprises:
a first supply line configured to supply a first fluid;
a second supply line configured to supply a second fluid; and
a spraying nozzle configured to spray a mixed fluid of the first fluid and the second fluid, and
wherein the curtain module comprises a third supply line for supplying the curtain body, and the curtain body is one of a deionized water (DIW), carbon dioxide (CO₂), and a mixed solution of the DIW and carbon dioxide (CO₂).

17. A substrate cleaning method comprising:
rotating an arranged substrate;
controlling a cleaning module to spray a cleaning solution on a surface of the substrate; and
controlling a curtain module, disposed on at least one of a first upper portion of an edge of the substrate and a second upper portion of an outside of the edge of the substrate, to spray a curtain body between a cleaner guard at least partially surrounding the substrate and at least one of an upper side of the edge of the substrate and the cleaning module, based on the cleaning module spraying the cleaning solution on the edge of the substrate.

18. The substrate cleaning method of claim 17, further comprising:
controlling a sensor to sense a position of the cleaning module disposed on the edge of the substrate.

19. The substrate cleaning method of claim 17, wherein the spraying of the cleaning solution comprises:
mixing a first fluid supplied from a first supply line and a second fluid supplied from a second supply line, resulting in a mixed cleaning solution; and
spraying the mixed cleaning solution through a spraying nozzle facing an upper side of the substrate.

20. The substrate cleaning method of claim 17, wherein the spraying of the curtain body comprises:
preventing droplets and particles generated by spraying of the cleaning solution from at least one of colliding with an internal wall of the cleaner guard and returning to the substrate, based on the curtain module spraying the curtain body in parallel to the internal wall of the cleaner guard.
